(19) United States
(12) Patent Application Publication
(10) Pub. No.: US 2008/0185972 A1
(43) Pub. Date: Aug. 7, 2008

(54) Light emitting display device

(75) Inventor: Katsuyuki Ito, Tokyo (JP)

Correspondence Address: TAKUCHI & KUBOTERA, LLP, Suite 202, 200 Daingerfield Road, Alexandria, VA, 22314, US

(73) Assignee: Oki Data Corporation

(21) Appl. No.: 12/000,498

(22) Filed: Dec. 13, 2007

(30) Foreign Application Priority Data
Dec. 22, 2006 (JP) 2006-345872

(51) Int. Cl. G09G 3/14; H01L 33/00

(52) U.S. Cl. 315/169.3; 257/89; 257/E33.056

(57) ABSTRACT

A light emitting display device includes a substrate processed to have a flat surface; a light emitting laminate thin film fixed to the flat surface of the substrate; a wiring portion connected to an electrode of the light emitting laminate thin film; and a drive unit connected to the wiring portion for driving the light emitting laminate thin film to emit light.

### BACKGROUND OF THE INVENTION AND RELATED ART STATEMENT

The present invention relates to a light emitting display device having a plurality of light emitting members. More specifically, the present invention relates to a light emitting display device having a light emitting element formed of a plurality of thin layers and arranged on a substrate.

In a conventional display device, a light emitting element such as a light emitting diode (LED) with high luminance is arranged on a substrate. In this case, an LED chip is fixed to the substrate using a silver paste or an adhesive. For example, when the LED chip is fixed to the substrate using a silver paste, the silver paste is applied in advance to a position on the substrate where the LED chip is fixed. Then, the LED chip is pushed onto the silver paste such that the silver paste is squeezed outside the LED chip, so that a bottom surface of the LED chip is fixed to the substrate. Then, the silver paste is heated and dried, thereby firmly fixing the LED chip to the substrate. Patent Reference has disclosed a method of fixing an LED chip, in which an amount of a silver paste is quantified.

### Patent Reference: Japanese Patent Publication No. 2000-244019

When the LED chip is fixed to the substrate using the silver paste or the adhesive, the LED chip may deform in the thermal processing step for setting the silver paste or the adhesive, thereby generating a stress in the LED chip due to the deformation. When such a stress is generated in the LED chip, light emitting efficiency may fluctuate with time while the LED chip emits light, thereby making it difficult to stably and uniformly emit light for display.

In view of the problems described above, an object of the present invention is to provide a light emitting display device, in which a light emitting element is fixed to a substrate such that the light emitting element stably and uniformly emits light.

Further objects and advantages of the invention will be apparent from the following description of the invention.

### SUMMARY OF THE INVENTION

In order to attain the objects described above, according to a first aspect of the present invention, a light emitting display device includes a substrate processed to have a flat surface; a light emitting laminate thin film fixed to the flat surface of the substrate; a wiring portion connected to an electrode of the light emitting laminate thin film; and a drive unit connected to the wiring portion for driving the light emitting laminate thin film to emit light.

In the first aspect of the present invention, the substrate has the flat surface processed through a flattening process. Accordingly, it is possible to fix the light emitting laminate thin film to the substrate through an intermolecular force. A bottom surface of the light emitting laminate thin film is fixed to the flat surface of the substrate, and the electrode is formed on a surface of the light emitting laminate thin film opposite to the bottom surface. A common wiring portion may be connected to electrodes of a plurality of light emitting laminate thin films.

According to a second aspect of the present invention, a light emitting display device includes a substrate; a plurality of light emitting laminate thin films fixed to and arranged on a surface of the substrate in a matrix pattern through an intermolecular force; anode electrodes formed on the light emitting laminate thin films; cathode electrodes formed on the light emitting laminate thin films; an anode wiring portion connected to the anode electrodes of the light emitting laminate thin films arranged in one row or one column of the matrix pattern; an anode drive unit connected to the anode wiring portion; a cathode wiring portion connected to the cathode electrodes of the light emitting laminate thin films arranged in another one row or another one column of the matrix pattern; and a cathode drive unit connected to the cathode wiring portion.

In the present invention, the substrate has the flat surface processed through a flattening process. Accordingly, it is possible to fix the light emitting laminate thin film to the substrate without applying a silver paste or an adhesive, thereby preventing a stress from generating in the light emitting laminate thin film. As a result, the light emitting display device can stably and uniformly display for a long period of time.

### BRIEF DESCRIPTION OF THE DRAWINGS

FIG. 1 is a block diagram showing a light emitting display device according to a first embodiment of the present invention;

FIG. 2 is a schematic view showing an LED (Light Emitting Diode) array panel of the light emitting display device according to the first embodiment of the present invention;

FIG. 3 is a schematic sectional view showing the LED array panel of the light emitting display device according to the first embodiment of the present invention;

FIG. 4 is a schematic sectional view showing an LED element of the LED array panel of the light emitting display device according to the first embodiment of the present invention;

FIGS. 5(a) to 5(f) are schematic sectional views showing a process of producing the LED array panel of the light emitting display device according to the first embodiment of the present invention;

FIGS. 6(a) to 6(f) are schematic sectional views showing another process of producing the LED array panel of the light emitting display device according to the first embodiment of the present invention; and

FIG. 7 is a schematic sectional view showing an LED array panel of a light emitting display device according to a second embodiment of the present invention.

### DETAILED DESCRIPTION OF PREFERRED EMBODIMENTS

Hereunder, embodiments of the present invention will be explained with reference to the accompanying drawings.

### First Embodiment

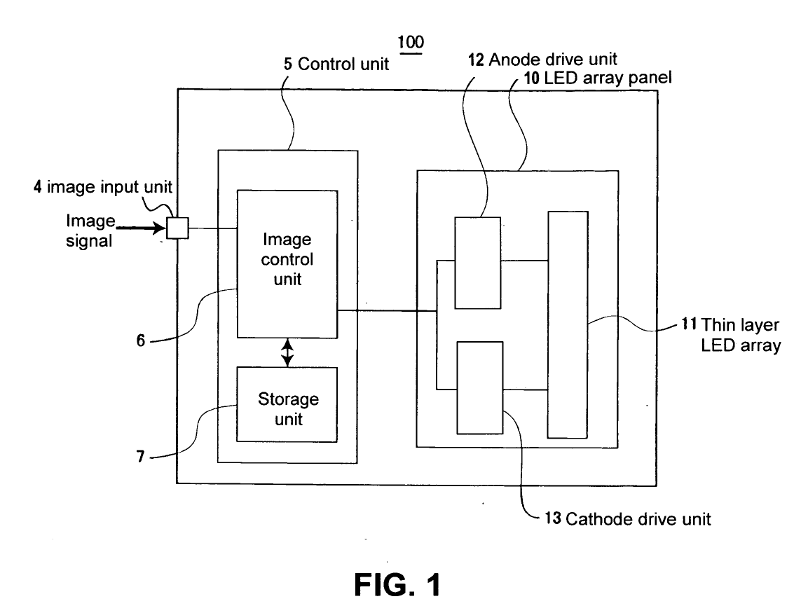

A first embodiment of the present invention will be explained. FIG. 1 is a block diagram showing a light emitting display device 100 according to a first embodiment of the present invention.

As shown in FIG. 1, the light emitting display device 100 includes an image input unit 4 for receiving an image signal from a host device such as a computer, an image device, and the likes. A control unit 5 includes an image control unit 6 with an image processing processor for converting the image signal input from the image input unit 4 to a format that an LED (Light Emitting Diode) array panel 10 can display, and for outputting the image signal with a control signal; and a storage unit 7 formed of a storage element such as a hard disk and a semiconductor memory for storing the image signal from the image control unit 6 and outputting the image signal thus stored to the image control unit 6.

In the embodiment, the image signal may contain a video image as well as a still image. The LED (Light Emitting Diode) array panel 10 includes an anode drive unit 12 and a cathode drive unit 13 for driving LED elements using the image signal converted at the image control unit 6; and a thin layer LED array 11 where the LED elements formed in a thin layer shape is arranged in a matrix pattern.

In the embodiment, the anode drive unit 12 supplies a current to each of the LED elements of the thin layer LED array 11 according to the image signal input from the image control unit 6. The anode drive unit 12 is formed of, for example, a shift register circuit, a latch circuit, a constant current circuit, a light amount correction circuit, and the likes. The cathode drive unit 13 receives a current from each of the LEDs of the thin layer LED array 11 according to the control signal input from the image control unit 6. The cathode drive unit 13 is formed of, for example, a switching element array, a scanning circuit, and the likes.

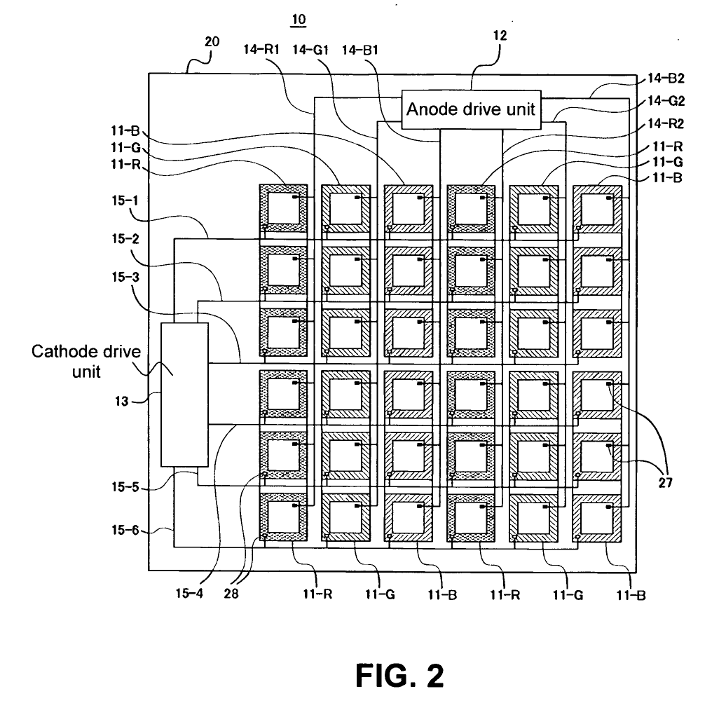

FIG. 2 is a schematic view showing the LED (Light Emitting Diode) array panel 10 of the light emitting display device 100 according to the first embodiment of the present invention. In FIG. 2, a matrix pattern is formed of six rows and six columns for simplifying the drawing, and an actual matrix pattern has a larger number of elements.

As shown in FIG. 2, thin layer LED arrays 11 (11-R, 11-G, 11-B) emitting a same color are arranged on a substrate 20 in a row direction (vertical direction in FIG. 2). The thin layer LED arrays 11 (11-R, 11-G, 11-B) emitting a different color are arranged in a column direction (horizontal direction in FIG. 2).

In the embodiment, the thin layer LED array 11-R emits a light in a red color frequency; the thin layer LED array 11-G emits a light in a green color frequency; and the thin layer LED array 11-R emits a light in a blue color frequency. One pixel is formed of a group of three thin layer LED arrays, i.e., the thin layer LED array 11-R, the thin layer LED array 11-G, and the thin layer LED array 11-B. The three thin layer LED arrays are independently driven, thereby obtaining a color image.

In the embodiment, a group of anode wiring portions 14 (14-R1 to 14-B2) connects the anode drive unit 12 to a p-side electrode 27 of each of the LED elements on the thin layer LED array 11, so that each row is commonly connected. Further, a group of cathode wiring portions 15 (15-1 to 15-6) connects the anode wiring portions 14 to an n-side electrode 28 of each of the LED elements on the thin layer LED array 11.

In the embodiment, the anode wiring portions 14 and the cathode wiring portions 15 are formed in a specific pattern, and formed of laminated thin layers of a metal material such as Au, Al, Ni, Ti, and the likes through a vapor deposition photolithography etching method or a lift-off method. An arrangement shown in FIG. 2 is just an example, and the thin layer LED arrays 11-R, 11-G, and 11-R may be arranged alternately in the vertical direction, or the light emitting display device 100 may emit light only one or two colors.

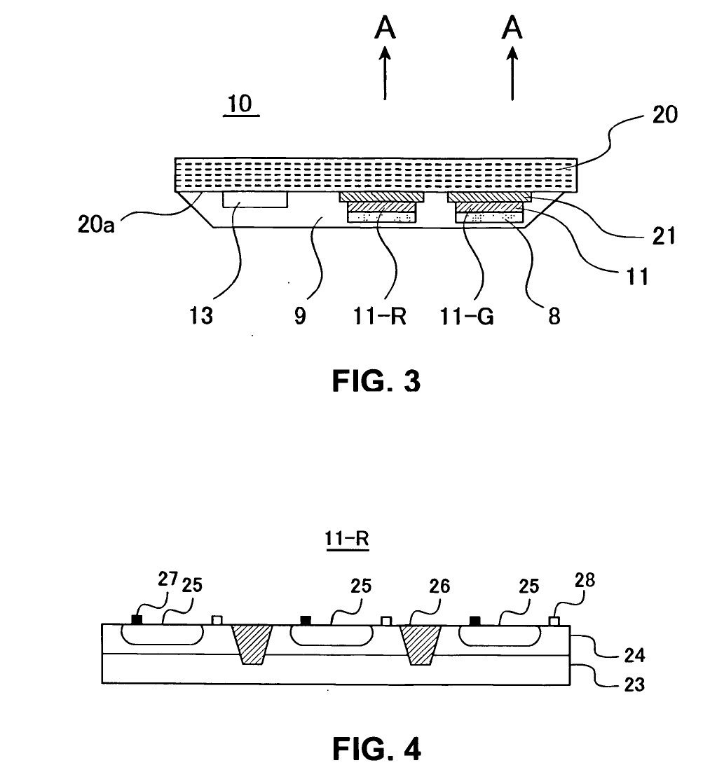

FIG. 3 is a schematic sectional view showing the LED array panel 10 of the light emitting display device 100 according to the first embodiment of the present invention. In FIG. 3, only the LED elements 11-R and 11-G arranged in two rows are shown.

As shown in FIG. 3, the anode drive unit 12, the cathode drive unit 13, and the thin layer LED array 11 are fixed to a component mounting surface 20a of the substrate 20 having a substantially flat plate shape. The substrate 20 is formed of a material transparent in a visible light range such as a glass, a resin, and the likes. A flattening film 21 is formed on the component mounting surface 20a of the substrate 20 using an organic material such as a polyimide film or an inorganic material. The flattening film 21 is formed to have an average roughness of less than few tenths of nanometers. Similar to the substrate 20, the flattening film 21 is formed of a material transparent in a visible light range.

In the embodiment, the LED elements 11-R and 11-G of the thin layer LED array 11 are fixed to a surface of the flattening film 21. Reflection films 8 are formed of gold and the likes for reflecting light emitting from the LED elements 11-R and 11-G of the thin layer LED array 11. A protective film 9 is formed of a silicone resin, an epoxy resin, and the likes, and covers the thin layer LED array 11, the anode wiring portions 14, the cathode wiring portions 15, and the likes for protecting the same.

In the embodiment, the anode drive unit 12 and the cathode drive unit 13 apply a specific potential to the LED elements 11-R and 11-G of the thin layer LED array 11 to selectively emit light. Accordingly, light generated at the LED elements 11-R and 11-G of the thin layer LED array 11 reflects on the reflection films 8 and is irradiated toward a backside surface of the substrate 20 in an arrow direction A through the flattening film 21 and the substrate 20.

FIG. 4 is a schematic sectional view showing the LED element 11-R of the LED array panel 11 of the light emitting display device 100 according to the first embodiment of the present invention. As described above, the LED elements of the thin layer LED array 11 include the three types, i.e., the LED elements 11-R emitting a light in a red color frequency (620 nm to 720 nm); the LED elements 11-G emitting a light in a green color frequency (500 nm to 580 nm); and the LED elements 11-R emitting a light in a blue color frequency (450 nm to 500 nm). In the specification, only the LED element 11-R will be explained.

As shown in FIG. 4, n-type semiconductor layers 24 are formed on a semiconductor layer 23. The semiconductor layer 23 is formed of a semi-conductive material or a non-doped material. The n-type semiconductor layers 24 are formed of GaAs doped with an n-type impurity. The semiconductor layer 23 is a layer epitaxially grown from, for example, a growth substrate with crystal compatibility. A p-type impurity, for example, zinc (Zn), is diffused from surfaces of the n-type semiconductor layers 24 to form p-type semiconductor layers 25. Accordingly, a p-n connection portion is created at a boundary between the n-type semiconductor layer 24 and the p-type semiconductor layer 25, so that the p-n connection portion emits light as an LED.

In the embodiment, element separation areas 26 are formed as separation grooves reaching the semiconductor layer 23 for electrically separating the n-type semiconductor layers 24. The element separation areas 26 are formed with an etching, and are filled with an insulation material to flatten a surface thereof.

In the embodiment, the p-side electrodes 27 are formed on the surfaces of the p-type semiconductor layers 25 for drawing p-side electrodes. The p-side electrodes 27 are formed of a metal thin film and electrically connected to the p-type semiconductor layers 25 corresponding thereto. The n-side electrodes 28 are formed on the surfaces of the n-type semiconductor layers 24 separated with the element separation areas 26 in areas where the p-type semiconductor layers 25 are not disposed. The n-side electrodes 28 are formed of a metal thin film and electrically connected to the n-type semiconductor layers 24 corresponding thereto.

In the description above, the LED element 11-R is explained in detail. Similarly, the LED element 11-G emitting a light in a green color frequency (500 nm to 580 nm) is formed of AlGaInP or GaP. The LED element 11-B emitting a light in a blue color frequency is formed of GaN or InGaN. Further, the semiconductor layers in the LED elements preferably have a hetero structure or a double hetero structure, and may have a multiple quantum well structure.

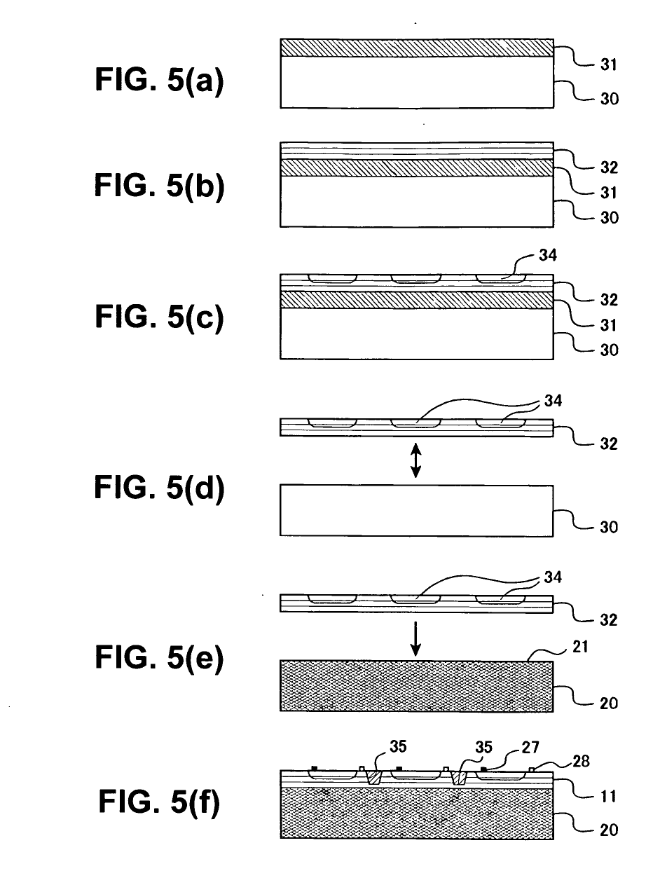

With reference to FIGS. 5(a) to 5(f), a process of producing the thin layer LED array 11 and the LED array panel 10 will be explained next. In the explanation, a process of producing the LED element 11-R emitting a light in a red color frequency will be explained. FIGS. 5(a) to 5(f) are schematic sectional views showing a process of producing the LED array panel 10 of the light emitting display device 100 according to the first embodiment of the present invention.

As shown in FIG. 5(a), a sacrifice layer 31 made of AlAs is formed as a thin layer on a mother substrate 30 formed of GaAs. The mother substrate 30 is prepared for an epitaxial growth process, and is different from the substrate 20.

In the next step, as shown in FIG. 5(b), a semiconductor thin film 32 is formed on the sacrifice layer 31 through the epitaxial growth process using a material such as AlGaAs and the likes with a gas phase growth method such as an MOCVD method. The semiconductor this film 32 corresponds to the semiconductor layer 23 formed of a semi-conductive material or a non-doped material, and the n-type semiconductor layer 24 formed of GaAs doped with an n-type impurity.

In the next step, as shown in FIG. 5(c), n-type areas 34 are formed in the semiconductor thin film 32 formed on the sacrifice layer 31, thereby forming the p-n connection portions or a plurality of LED elements.

After the n-type areas 34 or the LED elements are formed, the n-type areas 34 are processed through photolithography and an etching process using a phosphoric acid as an etchant, so that the n-type areas 34 are formed in a rectangular shape having a specific length and a specific width including a specific number of light emitting areas.

In the next step, the mother substrate 30 is immersed in a removal etching solution such as a hydrogen fluoride solution or a hydrochloric acid solution, thereby removing the sacrifice layer 31. As a result, as shown in FIG. 5(d), the mother substrate 30 is separated from the semiconductor thin film 32 with a plurality of LED elements formed thereon.

In the next step, as shown in FIG. 5(e), the semiconductor thin film 32 separated from the mother substrate 30 is pressed against and fixed to the flattening film 21 formed on the substrate 20 having a transparent property. In the embodiment, the flattening film 21 is preferably formed of an organic insulation thin film or an inorganic insulation film, and has a thickness less than 100 nm. When the flattening film 21 has a flat smooth surface with reduced roughness, it is possible to securely fix the semiconductor thin film 32 to the substrate 20 through an intermolecular force such as hydrogen bonding.

In the next step, as shown in FIG. 5(f), the semiconductor thin film 32 fixed to the substrate 20 is etched through photolithography and an etching process using a phosphoric acid as an etchant, thereby forming the thin film LED element 11-R. That is, separation grooves 35 are formed for electrically separating the adjacent p-type semiconductor areas through an etching process. Then, the separation grooves 35 are filled with an insulation material to be flattened. Then, as shown FIG. 4, the p-side electrodes 27 and the n-side electrodes 28 are formed through the vapor deposition photolithography etching method or the lift-off method. Accordingly, it is possible to produce the thin film LED element 11-R fixed to the substrate 20.

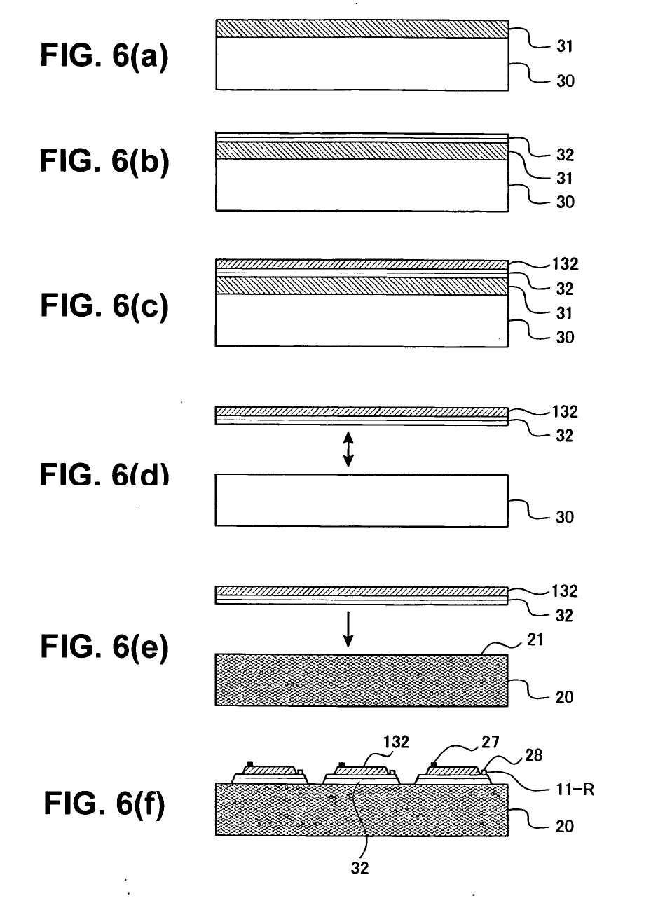

In the method described above, the LED element is formed through the selective diffusion process of the p-type area, and may be formed through a lamination process of the p-type semiconductor layer. FIGS. 6(a) to 6(f) are schematic sectional views showing another process of producing the LED array panel 10 the light emitting display device 100 according to the first embodiment of the present invention.

As shown in FIG. 6(a), the sacrifice layer 31 made of AlAs is formed as a thin layer on the mother substrate 30 formed of GaAs. The mother substrate 30 is prepared for an epitaxial growth process, and is different from the substrate 20.

In the next step, as shown in FIG. 6(b), the semiconductor this film 32 is formed on the sacrifice layer 31 through the epitaxial growth process using a material such as AlGaAs and the likes with a gas phase growth method such as an MOCVD method. The semiconductor this film 32 corresponds to the semiconductor layer 23 formed of a semi-conductive material or a non-doped material, and the n-type semiconductor layer 24 formed of GaAs doped with an n-type impurity. The process so far is the same as that shown in FIGS. 5(a) and 5(b).

In the next step, a p-type semiconductor film 132 is formed on a whole surface of the semiconductor thin film 32 formed on the sacrifice layer 31. When the p-type semiconductor film 132 is laminated, the p-n connection portion is formed at a boundary between p-type semiconductor film 132 and the semiconductor thin film 32, thereby forming the LED element.

After the p-type semiconductor film 132 is uniformly formed, the p-type semiconductor film 132 is processed through photolithography and an etching process using a phosphoric acid as an etchant, so that the p-type semiconductor film 132 and the semiconductor thin film 32 are formed in a rectangular shape having a specific length and a specific width including a specific number of light emitting areas.

In the next step, the mother substrate 30 is immersed in a removal etching solution such as a hydrogen fluoride solution or a hydrochloric acid solution, thereby removing the sacrifice layer 31. As a result, as shown in FIG. 6(d), the mother substrate 30 is separated from the p-type semiconductor film 132 and the semiconductor thin film 32 with a plurality of LED elements formed thereon.

In the next step, as shown in FIG. 6(e), the semiconductor thin film 32 and the p-type semiconductor film 132 separated from the mother substrate 30 are pressed against and fixed to the flattening film 21 formed on the substrate 20 having a transparent property. In the embodiment, the flattening film 21 is preferably formed of an organic insulation thin film or an inorganic insulation film, and has a thickness less than 100 nm. When the flattening film 21 has a flat smooth surface with reduced roughness, it is possible to securely fix the semiconductor thin film 32 and the p-type semiconductor film 132 to the substrate 20 through an intermolecular force such as hydrogen bonding.

In the next step, as shown in FIG. 6(f), the semiconductor thin film 32 and the p-type semiconductor film 132 fixed to the substrate 20 are etched through photolithography and an etching process using a phosphoric acid as an etchant, thereby forming the thin film LED element 11-R. That is, the separation grooves 35 are formed for electrically separating the adjacent p-type semiconductor areas through an etching process. Then, the separation grooves 35 are filled with an insulation material to be flattened. Then, as shown FIG. 4, the p-side electrodes 27 and the n-side electrodes 28 are formed through the vapor deposition photolithography etching method or the lift-off method. Accordingly, it is possible to produce the thin film LED element 11-R fixed to the substrate 20.

With reference to FIGS. 1 and 2, an operation of the light emitting display device 100 will be explained next. After the image input unit 4 receives the image signal, the image signal is temporarily stored in the storage unit 7 as the image data through the image control unit 6. Note that the operation is called as an image accumulation type, and the image signal thus input may be directly converted to the image data and the control signal to be output. Then, the image control unit 6 retrieves the image data stored in the storage unit 7, and outputs the image data together with the control signal to the anode drive unit 12 and the cathode drive unit 13.

In the next step, the anode drive unit 12 sequentially stores the image data input from the image control unit 6 per one scan in a shift resistor. One scan corresponds to one column arranged horizontally in FIG. 2, for example, the LED elements commonly connected to the cathode wiring portion 15-1. The image data controls whether the corresponding LED elements emit light.

When the image data per one scan are stored in the shift resistor of the anode drive unit 12, the image data per one scan are transferred to a latch circuit. According to the image data received from the image control unit 6, the cathode drive unit 13 selects and energizes the cathode wiring portion 15-1 as a first one. Accordingly, when data for emitting the corresponding LED elements are stored in the latch circuit of the anode drive unit 12, a constant current circuit and an amplifier circuit of the anode drive unit 12 supplies a current to the cathode wiring portion 15-1 through the p-side electrodes (cathode) and the n-side electrodes (anode) thereof, so that the corresponding LED elements emit light.

In the next step, the image data per one scan corresponding to the LED elements commonly connected to one of the cathode wiring portions 15 are sequentially stored, so that the corresponding one of the cathode wiring portions 15 is selected and energized. After all of scans are selected, the LED elements complete emitting light for one image. The scans may be selected sequentially, or through an interlace method.

In the embodiment, the LED array panel 10 has the LED elements arranged in the 6×6 matrix pattern (36 elements), and the LED elements may be arranged in an arbitrary pattern. Further, each of the light emitting portions may have an arbitrary shape having an arbitrary ratio of a lateral length and a vertical length; and may be arranged in an arbitrary pattern when the thin layer LED array 11 is produced. For example, similar to the embodiment, when the LED elements emitting three colors are arranged, three LED elements in three colors are preferably arranged in an area having a square shape, and may be arranged in an area having an arbitrary shape such as a diamond shape, a circular shape, an oval shape and the likes.

In the embodiment, the thin layer LED array 11 is arranged on the substrate 20 in a plane arrangement, and is not limited thereto. Different thin film LED arrays may be laminated and connected such that light emitting areas of LED elements of the LED arrays are not overlapped. Further, three LED elements in three colors are may be disposed in one chip.

As described above, in a conventional display device, when a LED chip is fixed to a substrate using a silver paste or an adhesive, the LED chip may deform in a thermal processing step for setting the silver paste or the adhesive, thereby generating a stress in the LED chip. When such a LED chip emits light, a light emitting efficiency may increases during first hundred hours, then decreases unevenly with time.

In the embodiment, the LED elements of the thin layer LED array 11 are fixed to the substrate 20 through an intermolecular force, thereby preventing a stress from generating in the LED elements. Accordingly, when the thin film LED array 11 emits light, a light emitting efficiency fluctuates within only 1% during first hundred hours, then the light emitting efficiency becomes stable with time, thereby making it possible to stably display.

In the embodiment, the thin film LED array 11 has a thickness of a few micrometers. Accordingly, the anode wiring portions 14 are directly connected over a step to the p-side electrodes 27 of the LED elements on the thin layer LED array 11. Similarly, the cathode wiring portions 15 are directly connected over a step to the n-side electrodes 28 of the LED elements on the thin layer LED array 11. Accordingly, it is possible to form the anode wiring portions 14 and the cathode wiring portions 15 through a vapor deposition photolithography etching method or a lift-off method, thereby making it easy to produce the light emitting display device 100, and possible to accurately dispose 14 and the cathode wiring portions 15.

As described above, in the embodiment, a plurality of semiconductor thin films having a plurality of light emitting elements is fixed to the substrate two-dimensionally in the matrix pattern. Then, the drive unit selectively drives the light emitting elements, so that the display unit displays an image and the likes. Accordingly, it is possible to prevent a stress due to deformation from generating in the light emitting elements when the light emitting elements of the semiconductor thin films are fixed to the substrate. As a result, the light emitting elements emit light with less fluctuation in the light emitting efficiency with time, and the display device can stably and uniformly display for a long period of time.

### Second Embodiment

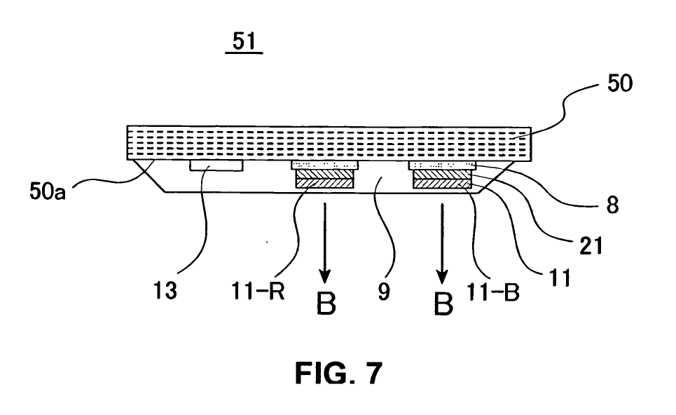

A second embodiment of the present invention will be explained next. FIG. 7 is a schematic sectional view showing an LED array panel of a light emitting display device according to a second embodiment of the present invention. In FIG. 7 similar to FIG. 3, only the LED elements 11-R and 11-G arranged in two rows are shown.

In the second embodiment, the anode drive unit 12 (not shown in FIG. 7), the cathode drive unit 13 (not shown in FIG. 7), and the LED elements 11-R and 11-G of the thin layer LED array 11 are mounted on a substrate 50.

In the second embodiment, the substrate 50 is formed of a material with high thermal conductivity such as a ceramic, a metal, and the likes. When the substrate 50 has high thermal conductivity, it is possible to prevent a temperature around the LED elements 11-R and 11-G from increasing.

In the embodiment, the substrate 50 is provided with the reflection films 8 formed on a component mounting surface 50a of the substrate 50 through a vapor deposition process and the likes using a metal such as Au, Al, and the likes. Further, the flattening film 21 is formed on the component mounting surface 50a using an organic material such as a polyimide film or an inorganic material. The flattening film 21 is formed to have an average roughness of less than few tenths of nanometers.

In the embodiment, the LED elements 11-R and 11-G are fixed to the flattening film 21, and the anode drive unit 12 is connected to the p-side electrodes of the LED elements on the thin layer LED array 11 through the anode wiring portions. Similarly, the cathode drive unit 13 is connected to the n-side electrodes of the LED elements on the thin layer LED array 11 through the cathode wiring portions. The protective film 9 is formed of a silicone resin, an epoxy resin, and the likes, and covers the thin layer LED array 11, the anode wiring portions 14, the cathode wiring portions 15, and the likes for protecting the same. Light generated at the LED elements 11-R and 11-G of the thin layer LED array 11 reflects on the reflection films 8 and is irradiated in an arrow direction B through the protective film 9. A heat sink may be disposed on a backside surface of the substrate 50. Further, a part of the reflection films 8 may be used as a wiring portion.

An operation of the light emitting display device 100 in the second embodiment is similar to that in the first embodiment. In the operation, due to the high thermal conductivity of the substrate 50, it is possible to effectively releasing heat of the thin layer LED array 11 outside the substrate through the reflection films 8 with high thermal conductivity and the flattening film 21 with an insulation property, low thermal resistivity, and a small thickness.

As described above, in the embodiment, a plurality of semiconductor thin films having a plurality of light emitting elements is fixed to the substrate with high thermal conductivity two-dimensionally in the matrix pattern. Then, the drive unit selectively drives the light emitting elements, so that the display unit displays an image and the likes. Accordingly, it is possible to prevent a stress due to deformation from generating in the light emitting elements when the light emitting elements of the semiconductor thin films are fixed to the substrate. As a result, the light emitting elements emit light with less fluctuation in the light emitting efficiency with time, and the display device can stably and uniformly display for a long period of time.

The disclosure of Japanese Patent Application No. 2006-345872, filed on Dec. 22, 2006, is incorporated in the application by reference.

While the invention has been explained with reference to the specific embodiments of the invention, the explanation is illustrative and the invention is limited only by the appended claims.

What is claimed is:

1. A light emitting display device, comprising:
a substrate having a flattened surface;
a light emitting laminate thin film fixed to the flattened surface, said light emitting laminate thin film including an electrode;
a wiring portion connected to the electrode; and
a drive unit connected to the wiring portion for driving the light emitting laminate thin film to emit light.

2. The light emitting display device according to claim 1, wherein said light emitting laminate thin film includes a first light emitting laminate thin film having a first LED (Light Emitting Diode) emitting light in a range of 620 nm to 720 nm, a second light emitting laminate thin film having a second LED emitting light in a range of 500 nm to 580 nm, and a third light emitting laminate thin film having a third LED emitting light in a range of 450 nm to 500 nm.

3. The light emitting display device according to claim 1, wherein said light emitting laminate thin film is formed through laminating a sacrifice layer on a mother substrate; laminating a plurality of layers on the sacrifice layer; and removing the sacrifice layer using an etchant.

4. The light emitting display device according to claim 1, further comprising an element separation area for electrically separating the light emitting laminate thin film.

5. The light emitting display device according to claim 1, further comprising a flattening film disposed on the substrate, said flattening film being formed of an organic insulation material or an inorganic insulation material.

6. The light emitting display device according to claim 5, wherein said flattening film has a surface roughness of less than 100 nm.

7. The light emitting display device according to claim 1, wherein said light emitting laminate thin film is fixed to the flattened surface through an intermolecular force.

8. The light emitting display device according to claim 1, wherein said wiring portion is formed of a deposited layer formed through a photolithography method or a lift-off method.

9. A light emitting display device, comprising:
a substrate;
a plurality of light emitting laminate thin layers fixed to the surface of the substrate through an intermolecular force, said light emitting laminate thin layers being arranged on the surface of the substrate in a matrix pattern;
anode electrodes formed on the light emitting laminate thin layers;
cathode electrodes formed on the light emitting laminate thin layers;
an anode wiring portion connected to the anode electrodes of the light emitting laminate thin layers arranged in one row or one column of the matrix pattern;
an anode drive unit connected to the anode wiring portion;
a cathode wiring portion connected to the cathode electrodes of the light emitting laminate thin layers arranged in another one row or another one column of the matrix pattern; and
a cathode drive unit connected to the cathode wiring portion.

10. The light emitting display device according to claim 1, wherein said substrate is formed of a transparent material.

11. The light emitting display device according to claim 9, wherein said substrate is formed of a transparent material.

12. The light emitting display device according to claim 1, wherein said substrate is formed of a material with high thermal conductivity.

13. The light emitting display device according to claim 9, wherein said substrate is formed of a material with high thermal conductivity.
